(19) United States
(12) Patent Application Publication
(10) Pub. No.: US 2013/0216728 A1
(43) Pub. Date: Aug. 22, 2013

(54) Continuous Low Vacuum Coating Apparatus

(71) Applicants: Christopher Hurren, Waurn Ponds (AU); Brian John Conolly, Northwood (AU); Thomas Kenneth Hussey, Balmain (AU)

(72) Inventors: Christopher Hurren, Waurn Ponds (AU); Brian John Conolly, Northwood (AU); Thomas Kenneth Hussey, Balmain (AU)

(21) Appl. No.: 13/768,850

(22) Filed: Feb. 15, 2013

(30) Foreign Application Priority Data
Feb. 16, 2012 (AU) 2012900561

(51) Int. Cl. C23C 16/54

(52) U.S. Cl. CPC C23C 16/54
USPC 427/551; 118/718; 427/569; 427/558; 427/559

(57) ABSTRACT

An apparatus for continuously forming a thin-film layer of organic or inorganic functional material on one or both sides of a flexible substrate via plasma enhanced vacuum vapour deposition.

### FIELD OF THE INVENTION

The present invention relates to an apparatus for continuously forming a thin-film layer of organic or inorganic functional material on one or both sides of a flexible substrate via plasma enhanced vacuum vapour deposition.

### BACKGROUND OF THE INVENTION

The term “functionalization” and related terminology are used in the art and herein to refer to the process of treating a material to alter its surface properties to meet specific requirements for a particular application. For example, the surface energy of a material may be treated to render it particularly hydrophobic or hydrophilic as may be desirable for a given use. Thus, surface functionalization has become common practice in the manufacture of many materials because it adds value to the end product. In order to achieve such different ultimate results, functionalization may be carried out in a variety of ways ranging from wet chemistry to various forms of vapor deposition, vacuum metallization and sputtering.

US Patent Application Publication US 2004/0213918 A1 (Mikhael et al.) discloses a process for functionalizing a porous substrate, such as a nonwoven fabric or paper, with a layer of polymer, and optionally a layer of metal or ceramic. According to one embodiment, the process includes the steps of flash evaporating a monomer having a desired functionality in a vacuum chamber to produce a vapor, condensing the vapor on the porous substrate to produce a film of the monomer on the porous substrate, curing the film to produce a functionalized polymeric layer on the porous substrate, vacuum depositing an inorganic layer over the polymer layer, and flash evaporating and condensing a second film of monomer on the inorganic layer and curing the second film to produce a second polymeric layer on the inorganic layer. Mikhael et al. also discloses another embodiment including the steps of flash evaporating and condensing a first film of monomer on the porous substrate to produce a first film of the monomer on the porous substrate, curing the film to produce a functionalized polymeric layer on the porous substrate, vacuum depositing a metal layer over the polymer layer, and flash evaporating and condensing a second film of monomer on the metal layer and curing the second film to produce a second polymeric layer on the metal layer.

U.S. Pat. No. 5,088,908 discloses a method of continuous vacuum plasma treatment and vacuum deposition of a flexible substrate wherein the substrate passes through a series of vacuum locks that feature opposing plates of close proximity that facilitate the required airlock. The method disclosed is not adequate in maintaining the required vacuum pressure for many substrates including porous and/or flexible substrates.

U.S. Pat. No. 4,507,539 discloses a method of continuous vacuum plasma treatment of a flexible substrate wherein the substrate passes through a single vacuum lock that features opposing rollers of close proximity that facilitate the required airlock.

U.S. Pat. No. 4,551,310 discloses a method of continuous vacuum plasma treatment of a plastic moulding wherein the substrate passes through a series of vacuum locks that feature opposing rollers of close proximity to facilitate the required airlock.

There currently exists no continuous method for vacuum plasma treatment followed by flash evaporation and deposition of a chemical onto a substrate.

For applications whereby it is desirable to have some amount of stretch of the functionalised composite, current coating processes have produced unsatisfactory results with reduced benefit of the functionalization of the outer exposed surface(s). In these cases, the said coating layers do not cover the underlying sub-surfaces of the substrate that are exposed only after stretching the material.

### SUMMARY OF THE INVENTION

In view of the foregoing, this invention is directed at an apparatus that is suitable for functionalizing a broad range of porous and non-porous substrates by means of vacuum plasma treatment and vacuum deposition in a continuous process.

In one embodiment of the present invention, said organic or inorganic coatings are applied to said substrate by the process of pre-treating the substrate in a vacuum plasma, flash evaporating a monomer or sol-gel having said functionality in a vacuum chamber to produce a vapour, condensing the vapour on the substrate to produce a film of said monomer or sol-gel on the surface of the substrate and curing the film to produce an organic or in-organic layer on the substrate. Whereby the said coatings are applied in a continuous process at a vacuum pressure that is low enough to enable vacuum plasma and vacuum vapour deposition of the said organic or inorganic compounds. Wherein the substrate enters and exits a treatment chamber through a series of vacuum locks designed to enable continuous running of flexible substrates.

In a further aspect of the present invention the said series of vacuum locks utilise a roller style vacuum seal between each chamber to maintain an adequate vacuum within the main treatment chamber. In a preferred embodiment, each vacuum chamber is evacuated by its own vacuum pump with pressures slightly higher than the vacuum pressure in the vacuum processing chamber.

In an alternate embodiment of the present invention, apparatus may feature machinery that controls the width (weft) and length (warp) of the substrate in order to facilitate the processing of a stretchable substrate and control the amount of pre-stretch of said substrate during processing.

In a further aspect of the present invention the apparatus may be configured with multiple plasma treatment heads, flash evaporator vapour deposition heads and curing units within one vacuum chamber to allow vacuum vapour deposition on one or both sides of the substrate. In an alternate embodiment, the apparatus may be configured so that said multiple heads are configured in a series of plasma treatment head, flash evaporator vapour deposition head and curing head and each series is contained within a separate vacuum chamber separated by a vacuum lock.

### BRIEF DESCRIPTION OF THE DRAWINGS

FIG. 1 is a schematic diagram of an apparatus suitable for forming the material of the present invention.

FIG. 2 is a schematic diagram of an alternate apparatus suitable for forming the material of the present invention

FIGS. 3a and 3b are schematic diagrams of the apparatus in FIG. 2 showing how the same apparatus can continuously form a thin-film layer of organic or inorganic functional material on either side.

FIGS. 4 and 5 are schematic diagrams of the apparatus in FIG. 2 showing how the same apparatus can daisy chain in a modified way, and substantially share the same vacuum, and continuously form a thin-film layer of organic or inorganic functional material on either side cascaded together to coat on both sides, or multiple times to either side.

### DETAILED DESCRIPTION OF THE INVENTION

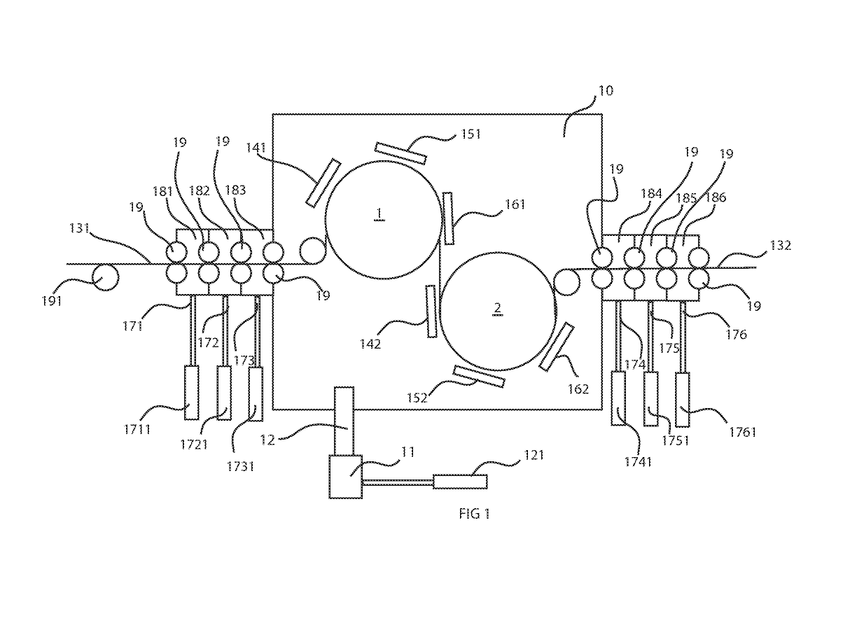

As shown in FIG. 1, the substrate (131) is removed from a storage device or a piece of upstream processing equipment in a flat open geometry. This may be facilitated with the use of scroll rollers (191) before the first preliminary vacuum chamber (181) entry. The substrate enters the preliminary chamber between two rollers (19). A seal is maintained between these two rollers and the first preliminary vacuum chamber to prevent vacuum leakage of air into the chamber (181). The rollers of the vacuum seal (19) are made of a hard substance, like metal, and may be coated in an elastic material similar or identical to those used for the pad application of chemicals in wet finishing. The rollers are held against each other so that the rollers push the substrate flat minimising the movement of air through its structure and making a seal with the substrate surface. After passing through the rollers the fabric enters the first preliminary vacuum chamber (181). The fabric passes from the first preliminary chamber (181), to the second chamber (182), to the third chamber (183) and then to the main treatment chamber (10). The fabric passes through an identical roller style vacuum seal (19) as detailed above as it passes from one vacuum chamber into the next.

Each of the preliminary vacuum chambers is evacuated by its own vacuum pump (1711, 1721 and 1731 respectively) connected via a vacuum port (171, 172 and 173 respectively) so as to provide vacuum in the chamber with pressures slightly higher than the vacuum pressure in the vacuum processing chamber (10). The first vacuum chamber (181) may have a higher pressure than subsequent chambers due to degassing from the substrate. The length of each of the preliminary vacuum chambers may need to be increased or a fabric accumulator placed inside of them for particular fabrics to enable effective degassing of the material before it enters the main processing chamber by increasing its residence time within the vacuum lock. The void area of the preliminary vacuum chambers should be kept to a minimum. The first preliminary vacuum pump connected to port (171) will need to be bigger than subsequent preliminary vacuum pumps.

In the main treatment chamber The fabric passes around a large diameter chilled roller (1) where the first side of the fabric is treated and then around a second chilled roller (2) where the fabric is treated on the second side. Around the first roller (1) the treatment elements are a plasma treatment (141), a flash vapour deposition unit (151) and a curing unit (161). These same treatment units are duplicated around the second treatment large diameter treatment roller (2) with plasma treatment (142), a flash vapour deposition unit (152) and a curing unit (162). The curing unit is a heat or electron source curing unit and can include Ultra Violet (UV) light, electron beam and Infra Red. The surface speed of the large diameter treatment rollers is generally in the range of 1 to 1000 cm/second, however can be faster in some applications. More than one sequence of treatment can occur around each of the large diameter rollers. This is achieved by increasing the roller diameter and adding in additional plasma, vapour deposition and curing heads. The roller is cooled to facilitate with the deposition of monomer or sol-gel vapour from the flash evaporator.

Vacuum for the treatment area of the chamber is provided by a vacuum pump (121) connected to the chamber via vacuum port (12). The vacuum pump evacuates the chamber to the desired pressure 2×10-4 to 2×10-5 Torr (2.66×10-5 to 2.66×10-6 kPa), or other pressure as required in the coating chemistry or application. The vapours exiting from the vacuum port (12) first pass through a separating device (11) where residual polymer vapour is condensed from the vapour and collected for reuse, recycle or disposal.

The optional plasma treatment unit (141) is where the surface of the substrate is exposed to a plasma to remove adsorbed oxygen, moisture, and any low molecular weight species on the surface of the substrate prior to forming the monomer coating thereon. The surface energy of the substrate is generally modified to improve wetting of the surface by the coating layers. The plasma source may be low frequency RF, high frequency RF, DC, or AC. Suitable plasma treatment methods are described in U.S. Pat. No. 6,066,826, WO 99/58757 and WO 99/59185.

The flash vapour deposition unit (151) allows the application of an organic or in-organic layer onto the substrate. In one embodiment, organic monomer or sol-gel is deposited on the moisture vapour permeable substrate layer by monomer evaporator, which is supplied with liquid monomer or sol-gel solution from a reservoir through an ultrasonic atomizer, where, with the aid of heaters, the monomer or sol-gel liquid is instantly vaporized, i.e., flash vaporized, so as to minimize the opportunity for polymerization or thermal degradation prior to being deposited on the substrate layer. The monomer, oligomer, sol-gel solution or low molecular weight polymer liquid or slurry is preferably degassed prior to injecting it as a vapour into the vacuum chamber, as described in U.S. Pat. No. 5,547,508, which is hereby incorporated by reference. The specific aspects of the flash evaporation and monomer deposition process are described in detail in U.S. Pat. Nos. 4,842,893; 4,954,371; and 5,032,461, all of which are incorporated herein by reference.

The flash-vaporized monomer or sol-gel solution condenses on the surface of the substrate and forms a liquid monomer or sol-gel film layer. The monomer or sol-gel coating layer so that the composite substrate has a moisture vapour permeability of at least about 80% of the starting substrate layer. The condensed liquid monomer or sol-gel is solidified within a matter of milliseconds after condensation onto the substrate using a radiation or heat curing means (161). Suitable radiation and heat curing means include electron beam, infra red and ultraviolet radiation sources which cure the monomer or sol-gel film layer by causing polymerization or cross-linking of the condensed layer. If an electron beam gun is used, the energy of the electrons should be sufficient to polymerize the coating in its entire thickness as described in U.S. Pat. No. 6,083,628, which is incorporated herein by reference. The polymerization or curing of monomer and oligomer layers is also described in U.S. Pat. Nos. 4,842,893, 4,954,371 and 5,032,461. Alternately, an oligomer or low molecular weight polymer can solidify simultaneously with cooling. For oligomers or low MW polymers that are solid at room temperature, curing may not be required as described in U.S. Pat. No. 6,270,841 that is incorporated herein by reference. Alternatively a sol-gel solution can be cured by the addition of heat to the coating film.

The thickness of the coating is controlled by the line speed and vapour flux of the flash evaporator used in the vapour deposition process. As the coating thickness increases, the energy of the electron beam must be adjusted in order for the electrons to penetrate through the coating and achieve effective polymerization. For example, an electron beam at 10 kV and 120 mA can effectively polymerize acrylate coatings up to 2 μm thick.

Coatings can be applied on the reverse side of the composite through use of a second rotating drum (2) that can be added within the vacuum chamber (10), with additional plasma treatment units (142), monomer evaporator (152) and curing means (162) which can be operated independently as desired. Such a dual-drum coating system is illustrated in FIG. 1 of WO 98/18852, which is incorporated herein by reference.

The exit vacuum lock is the same as that described for the entrance of the treatment chamber. The substrate leaves the chamber via the multiple vacuum locks (184, 185 and 186). Each of these vacuum locks have their own vacuum pump (1741, 1742 and 1743 respectively) and vacuum port (174, 175 and 176 respectively).

At any part of the above process, a stretchable substrate may be processed with additional modification to the treatment equipment. The substrate is placed in the path of the coating and plasma treatment parts of the machinery in a way that controls the stretch in both the width (weft) and the length (warp) of the substrate. This can occur in a number of ways including the two detailed below.

Before width control, the substrate first passes over a scroll roller to ensure that the substrate is open in its width. The amount of scroll rolling required will depend on the way that the substrate is presented to the scroll roller. If it is drawn directly from a roll and passed over the scroll roller then it will not require as much scroll intervention as a substrate coming from a roll some distance away or from an unrolled substrate. Automated width (weft) straitening by bowed rollers could also be part of the process just before scroll rolling if required. For substrates that feature a textile fabric, after scroll rolling, each selvedge could be passed through either rotating selvedge un-curler or selvedge uncurling plates or another method of selvedge uncurling. The substrate is then ready to be placed onto the method of width (warp) and length (weft) control.

A preferred method of width (weft) control is to place the open width substrate onto a belt of the same width (or wider) that provides resistance to the surface of the substrate. This resistance stops the substrate from sliding over its surface and curling on the edges. The resistance could be caused by surface roughness and/or a pile like structure and/or an adhesive and/or a static treatment. An example of a suitable pile like structure is a velour fabric. The fabric of the belt can then be directed around the treatment drum so that the substrate is presented to the treatment zones in the standard format detailed in this document.

Another preferred method of length (weft) control is to place the substrate onto a pinned or clipped belt. This belt would be similar to or the same as those used in fabric drying equipment. The equipment to place the substrate onto the belt would be similar to or the same as that used in this equipment and would include underfeed and overfeed devices on either edge of the edge of the substrate. The distance between the pin frames could also be increased or decrease to allow control of the level of stretch applied to the fabric as it goes through the treatment zone.

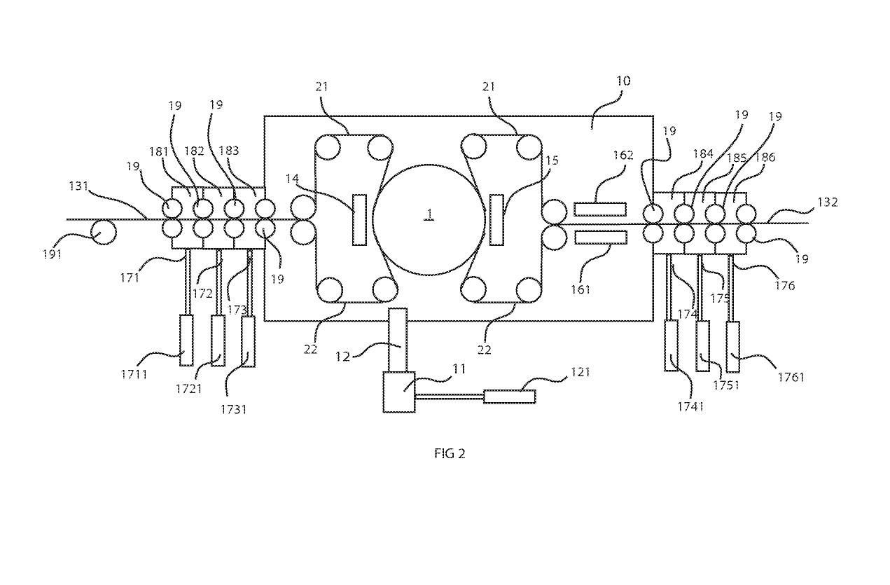

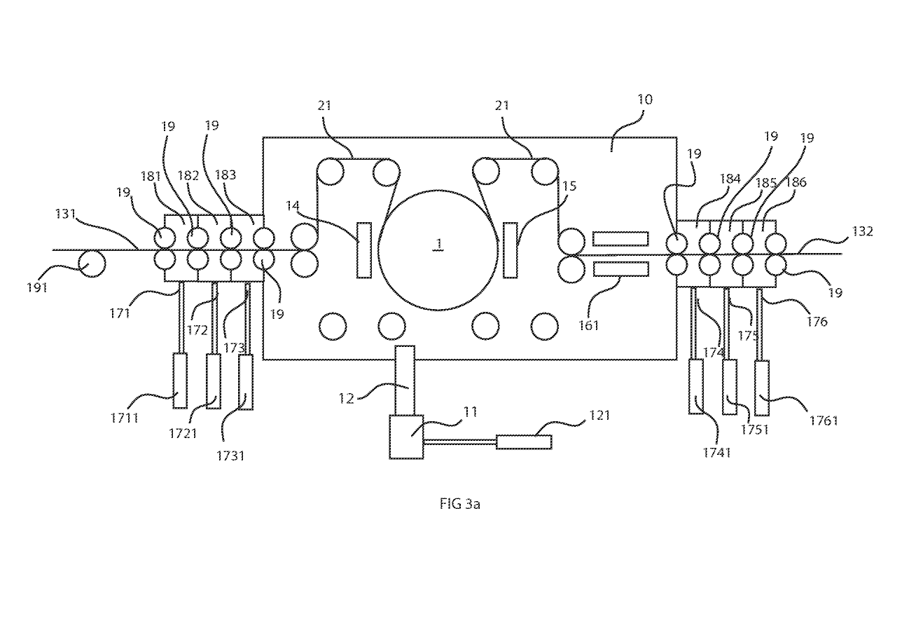

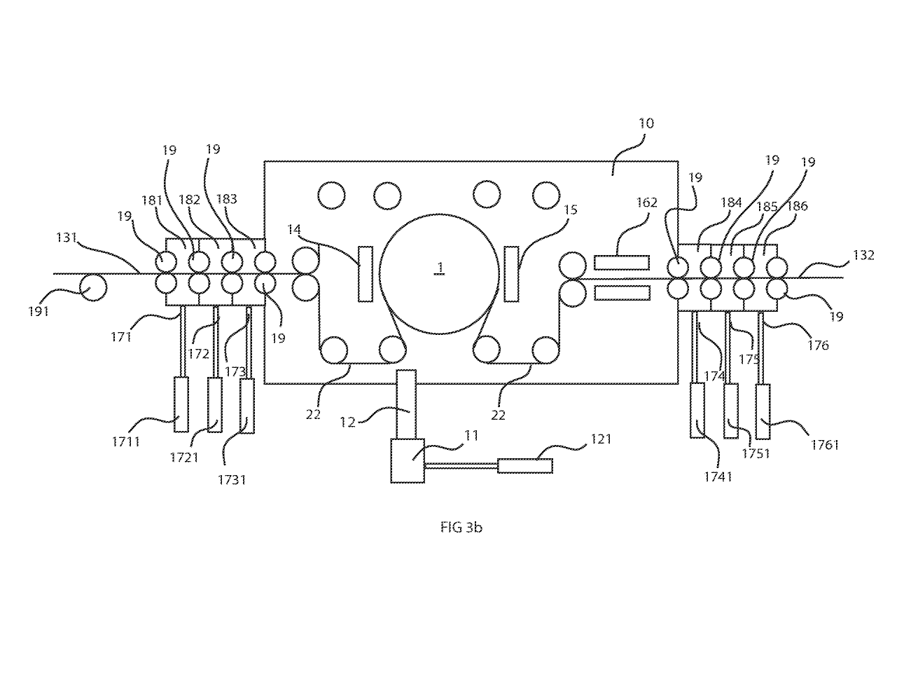

The apparatus shown in FIG. 2 is similar to that in FIG. 1 and shares the same design of vacuum lock at the feed and exit end of the chamber. The internal chamber (10) is different to that of FIG. 1 due to the placement of the feed system (21) and (22), the plasma treatment zone (14), the flash vapour deposition system (15) and the curing units (161) and (162). The chamber has been changed so that the one chamber can be used to coat either the top or the bottom of a substrate without modification of the equipment. The description of each of the components given for FIG. 1 are the same for FIG. 2. FIG. 3a shows the coating of the bottom of the substrate as it travels around the treatment drum (1). The substrate is fed via the upper feed roller system (21) to enter the drum from above. The bottom of the substrate is then exposed to the plasma unit (14) and then the flash vapour deposition system (15) before leaving the treatment drum via the upper feed roller system (21). The coating is cured via the curing units (161 and 162) before it exits the chamber. The curing units (161 and 162) can be used in tandem or individually for single sided coatings.

FIG. 3b shows the coating of the top of the substrate as it travels around the treatment drum (1). The substrate is fed via the lower feed roller system (22) to enter the drum from below. The top of the substrate is then exposed to the plasma unit (14) and then the flash vapour deposition system (15) before leaving the treatment drum via the lower feed roller system (22). The coating is cured via the curing units (161 and 162) before it exits the chamber. The curing units (161 and 162) can be used in tandem or individually for single sided coatings.

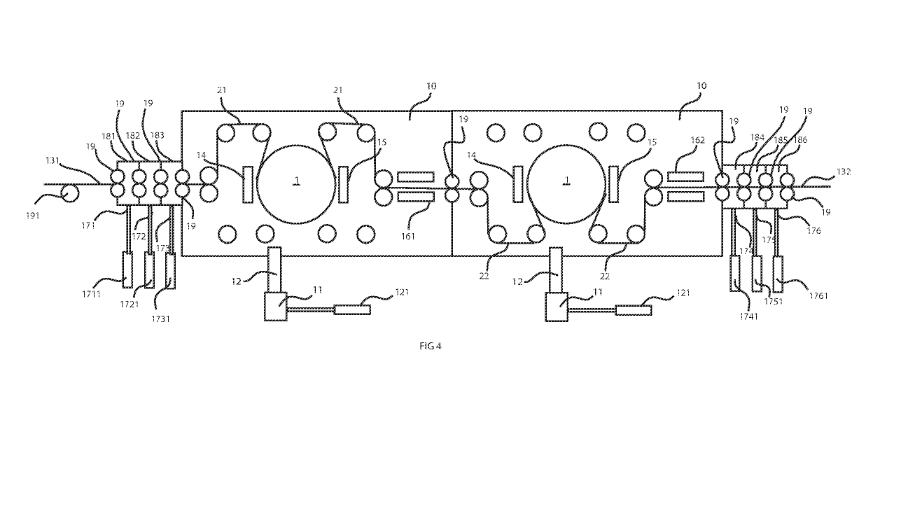

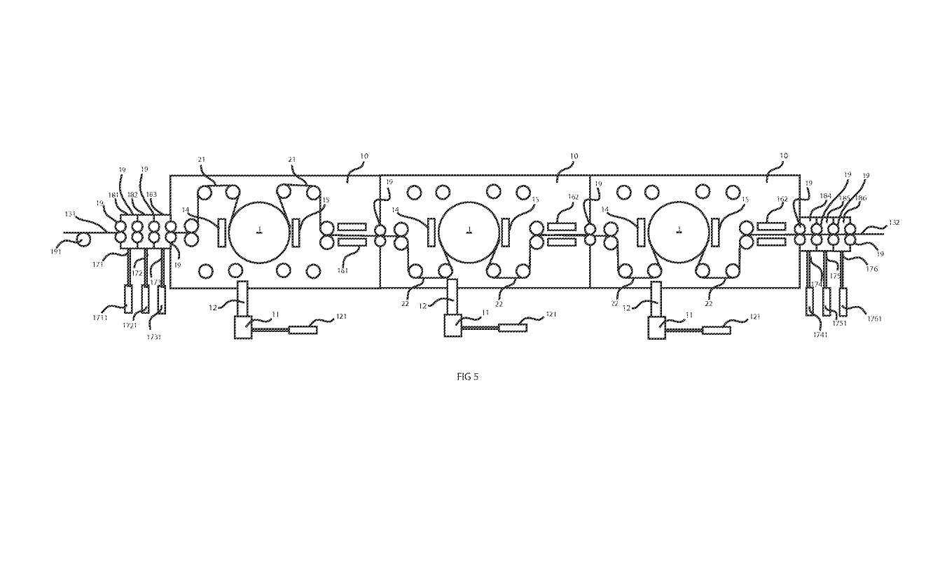

The changes to the chamber allow for more than one unit to be used in series FIGS. 4 and 5. This enables coatings on each side of the substrate without cross contamination of coating chemistry. The changes also allow for higher levels of flexibility in the coating equipment. Each vacuum chamber would have its own vacuum pump (121), condensing chamber (11) and vacuum port (12). Separate vacuum chambers and vacuum pump systems enable the unspent coating chemistry to be collected and reused/recycled without the risk of cross contamination via the other coating process.

FIG. 4 shows a machine layout where the substrate is coated on each side by a different coating chemistry.

FIG. 5 shows a machine layout where the substrate is coated with one coating chemistry on the bottom and then two layers of coating chemistry on the top of the fabric. Multiple chambers can be put in sequence in order to allow multiple layer coatings on a substrate surface.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Although the present invention has been described with particular reference to certain preferred embodiments thereof, variations and modifications of the present invention can be effected within the spirit and scope of the following claims.

What is claimed is:

1. An apparatus for continuously forming at least one thin-film layer of functional material on at least one side of a flexible substrate via plasma enhanced vacuum vapour deposition comprising:
a. upstream and downstream vacuum locks to allow entry and exit of the substrate into and out of a treatment chamber;
b. at least one plasma treatment zone to enable treatment of at least one side of the substrate;
c. at least one deposition head to enable application of the layer onto the surface of the substrate being coated; and
d. a curing zone to enable curing of the layer;
wherein the at least one head is selected from the group consisting of a chemical deposition head and a vapour deposition head, and
wherein the curing zone comprises a source selected from the group consisting of a heating source, an electron beam source, an ultra violet source, and an infra red source.

2. The apparatus of claim 1 wherein the treatment chamber is evacuated to a vacuum pressure range of 10⁻³ to 10⁻¹ mbar.

3. The apparatus of claim 1, wherein a geometry of the plasma treatment zone, deposition head and curing unit enable at least one layer to be applied to one side of the substrate only.

4. The apparatus of claim 3, wherein a geometry of a feed device to the plasma treatment zone, deposition head and curing unitenables at least one layer to be applied to either side of the substrate within the treatment chamber.

5. The apparatus of claim 1, further comprising multiple plasma treatment heads, deposition heads and curing units; wherein the geometry of said multiple plasma treatment heads, deposition heads and curing units enable at least one layer to be applied to each side of the substrate.

6. The apparatus of claim 5, wherein said multiple plasma treatment heads, deposition heads and curing units are contained within the one vacuum chamber.

7. The apparatus of claim 5, wherein said multiple plasma treatment heads, deposition heads and curing units are in series of plasma treatment head, deposition head and curing head, and each series is contained within a separate vacuum chamber separated by a vacuum lock.

8. The apparatus of claim 1, wherein said treatment chamber comprises a combination of zones wherein each zone may include either
multiple plasma treatment heads, deposition heads and curing units are contained within one vacuum chamber; or,
multiple plasma treatment heads, deposition heads and curing units in series of plasma treatment head, deposition head and curing head, wherein each series is contained within a separate vacuum chamber separated by a vacuum lock.

9. The apparatus of claim 1 further comprising a chemical separator to facilitate unspent coating chemical recovery.

10. The apparatus of claim 1 further comprising a width stretch controller for controlling the stretch of the width of a substrate as it is coated with said functional material.

11. The apparatus of claim 1 further comprising a length stretch controller for controlling the stretch of the length of a substrate as it is coated with said functional material.

12. The apparatus according to claim 1, further comprising a belt with resistance created by surface roughness and/or a pile structure and/or an adhesive and/or static treatment that holds the substrate in a desired amount of stretch as the substrate is coated with said functional material.

13. The apparatus according to claim 1, further comprising a pinned or clipped belt that can be adjusted to control a level of stretch of the substrate as it is coated with said functional material.

14. The apparatus according to claim 1, further comprising a preparing device for preparing said substrate for stretch control, the preparing device selected from the group consisting of a bowed roller, a rotating selvedge uncurler, and a selvedge uncurling plate.

15. A method for continuously forming at least one thin-film layer of functional material on at least one side of a flexible substrate via plasma enhanced vacuum vapour deposition comprising:
a. upstream and downstream vacuum locks to allow entry and exit of the substrate into and out of a treatment chamber;
b. at least one plasma treatment zone to enable treatment of at least one side of the substrate;
c. at least one deposition head to enable application of the layer onto the surface of the substrate being coated; and
d. a curing zone to enable curing of the layer;
wherein the at least one head is selected from the group consisting of a chemical deposition head and a vapour deposition head, and
wherein the curing zone comprises a source selected from the group consisting of a heating source, an electron beam source, an ultra violet source, and an infra red source.
